(19) United States
(12) Patent Application Publication
(10) Pub. No.: US 2023/0236250 A1
(43) Pub. Date: Jul. 27, 2023

(54) BATTERY VOLTAGE PREDICTION APPARATUS AND METHOD

(71) Applicants: HYUNDAI MOTOR COMPANY, Seoil (KR); KIA CORPORATION, Seoul (KR); HONGIK UNIVERSITY INDUSTRY-ACADEMIA COOPERATION FOUNDATION, Seoul (KR)

(72) Inventors: Jung Hwan Bang, Seoul (KR); Jung Woo Noh, Bucheon-si (KR); Sung Jin Park, Seoul (KR); Jee Hwan Jeon, Seoul (KR)

(73) Assignees: HYUNDAI MOTOR COMPANY, Seoul (KR); KIA CORPORATION, Seoul (KR); HONGIK UNIVERSITY INDUSTRY-ACADEMIA COOPERATION FOUNDATION, Seoul (KR)

(21) Appl. No.: 17/992,363

(22) Filed: Nov. 22, 2022

(30) Foreign Application Priority Data
Jan. 26, 2022 (KR) 10-2022-0011232

(51) Int. Cl. G01R 31/367; G01R 31/382; H02J 7/00

(52) U.S. Cl. CPC G01R 31/367; G01R 31/382; H02J 7/0047

(57) ABSTRACT

A battery voltage prediction apparatus may include: a state-of-charge (SOC) derivation unit configured to derive the SOC of a battery according to a current that is input or output to the battery and a capacity of the battery; a fixed parameter derivation unit configured to derive fixed parameters required for an equivalent circuit model based on voltages measured according to input/output currents of the battery and a time change within a preset time when the current is input or output for the preset time; and a tuning parameter derivation unit configured to derive at least one tuning parameter that varies depending on a time required for the equivalent circuit model when the current is input or output for a time exceeding the preset time.

### CROSS REFERENCE TO RELATED APPLICATION

This application claims under 35 U.S.C. §119(a) the benefit of priority to Korean Patent Application No. 10-2022-0011232 filed on Jan. 26, 2022, the entire contents of which are incorporated herein by reference.

### BACKGROUND

### (A) Technical Field

The present disclosure relates to a battery voltage prediction apparatus and method that model a battery voltage prediction model for predicting the battery voltage.

### (B) Background Art

A model-based on-line simulation is used for the development of today’s vehicle controllers and parts in order to shorten development time while satisfying the demands for various functions. The most important thing in the on-line simulation is the accuracy of the model. In particular, in the development of eco-friendly vehicles, the accuracy of a battery model is so important in that the performance of a battery used as an energy storage system is the performance of eco-friendly vehicles.

A battery is a device configured to generate electrical energy by a chemical reaction. A battery is difficult to model relatively accurately because the battery has non-linear characteristics greatly affected by ambient temperature, capacity, internal resistance, and the like. Various methods of modeling batteries are currently proposed.

A representative model for simulating a battery includes a chemical reaction-based model and an equivalent circuit-based model. However, it is difficult for the chemical reaction-based model to be applied to predict an output voltage of a battery due to a slow operation speed. In addition, it is difficult for the equivalent circuit-based model to predict the battery output voltage with high reliability according to the amount of current and the time of applying the current by applying fixed parameters. To solve this problem, an equivalent circuit model to which a plurality of RC branches are added may be applied. However, there is a problem in that a process for extracting the parameters of the equivalent circuit model is complicated and takes a long time to calculate.

In particular, there is a problem in that the hybrid pulse power characterization (HPPC) discharge test that applies charge/discharge currents to the battery for 10 seconds may not simulate the voltage change (diffusion) due to the transfer of ions that are a material inside the battery. The transfer of ions occurs over a relatively long time.

The above information disclosed in this Background section is only to enhance understanding of the background of the disclosure. Accordingly, the Background section may include information that does not form the prior art that is already known to a person of ordinary skill in the art.

### SUMMARY OF THE DISCLOSURE

An object of the present disclosure is to provide a battery voltage prediction apparatus and method, which model, i.e., simulate, derive, achieve, generate, or create, etc., a battery voltage prediction model for predicting a battery voltage.

Another object of the present disclosure is to provide a battery voltage prediction apparatus and method, which apply a variable resistor and a variable capacitor in order to model a battery voltage prediction model. The apparatus and the method also apply tuning parameters in order to define the variable resistor and the variable capacitor varying over time that are applied to an equivalent circuit model in a section of tuning a state of charging of the battery in a process of testing the variable resistor and the variable capacitor.

According to an embodiment of the present disclosure, a battery voltage prediction apparatus for modeling a battery voltage prediction model may predict an output voltage of a battery over time by charging and discharging a current for each state of charge (SOC) of the battery. The apparatus includes an SOC derivation unit configured to derive the SOC of the battery according to a current that is input or output to the battery and a capacity of the battery. The apparatus also includes a fixed parameter derivation unit configured to derive fixed parameters required for an equivalent circuit model based on voltages measured according to input/output currents of the battery and a time change within a preset time when the current is input or output for the preset time. The apparatus also includes a tuning parameter derivation unit configured to derive at least one tuning parameter that varies depending on a time required for the equivalent circuit model when the current is input or output for a time exceeding the preset time.

In one example, the equivalent circuit model is a model for predicting the output voltage of the battery and configured to a voltage source representing an open-circuit voltage (OCV) of the battery, a fixed resistor connected to the voltage source in series, and an RC branch of a variable resistor and a variable capacitor.

In one example, the tuning parameter includes a first tuning parameter multiplied by a resistor of an RC branch configuring the equivalent circuit model and a second tuning parameter representing a time constant of the RC branch varying over time when the charge/discharge pulse currents are applied for a time exceeding the preset time. The output voltage of the battery at which the current is charged or discharged for a time exceeding preset time is predicted by the equivalent circuit model to which the tuning parameter is applied.

In one example, a section in which the current is input or output for a time exceeding the preset time means a section in which the SOC of the battery is tuned.

In one example, the fixed parameter derivation unit derives the fixed parameter in the section in which the current is input or output according to a constant period for the preset time.

In one example, the current that is input or output to the battery is a pulse current that is changed according to the constant period for the preset time.

In one example, one period in which a voltage of the battery is tested in a specific SOC of the battery is configured to include a current input/output section in which charge/discharge pulse currents are alternately applied for the preset time, a tuning section in which the SOC of the battery is tuned, and a rest period in which no current is applied.

In one example, the fixed parameter derivation unit derives the fixed parameter including a resistance value and a capacitance configuring the equivalent circuit model in the current input/output section. The fixed parameter derivation unit derives an OCV of the battery that is an output voltage at a time point at which the rest period ends. The tuning parameter derivation unit derives the tuning parameter in the tuning section.

In one example, the battery voltage prediction apparatus further includes a data storage unit configured to store the fixed parameter and the tuning parameter derived differently for each SOC of the battery.

In one example, the output voltage of the battery is defined according to the following equation:

$${V}_{e s t} = {V}_{O C V} + I ∗ {R}_{0} + {I}_{{R}_{1}} ∗ {R}_{{1}_{a d a p t i v e}} ∗ {e}^{- \frac{t}{τ}} + I ∗ {R}_{{1}_{a d a p t i v e}} ∗ \left(1 - {e}^{- \frac{t}{τ}}\right) .$$

In the equation, Vₑₓₜ is the estimated output voltage of the battery, V_{OCV} is the open-circuit voltage, R₀ is the fixed resistor, R_{1_{adaptive}} is the resistance value that varies over time and a value obtained by multiplying R₁ that is the resistor connected in parallel with the variable capacitor C1 by the first tuning parameter, and T is the second tuning parameter representing the time constant that is the tuning parameter of R₁ and the variable capacitor.

In one example, the R₀, the R₁, the capacitance, and the open-circuit voltage are derived by the fixed parameter derivation unit. The tuning parameter derivation unit derives the first tuning parameter and the second tuning parameter that vary according to a current application time when the current is input or output for a time exceeding the preset time. The second tuning parameter is derived by adding a value obtained by subtracting the preset time from a current application time to a constant value.

In one example, the first tuning parameter is defined according to the following equation:

$$\text{First tuning parameter} = \left\{\begin{matrix}1 , & t \leq p r e s e t t i m e \\ a {e}^{b t} + c {e}^{d t} , & t > p r e s e t t i m e\end{matrix}\right)$$

In this equation, t is the current application time, and a, b, c, and d are constants determined by the test.

According to an embodiment of the present disclosure, a battery voltage prediction method of modeling a battery voltage prediction model is provided and may predict an output voltage of a battery over time by charging and discharging a current for each SOC of the battery. The method includes deriving a fixed parameter required for an equivalent circuit model based on voltages measured according to a time change by applying charge/discharge pulse currents for a preset time to the battery in a specific SOC of the battery. The method also includes deriving at least one tuning parameter that varies according to a time required for the equivalent circuit model in a current input/output section for a time exceeding the preset time to the battery in order to change the SOC of the battery. The method also includes deriving an open-circuit voltage of the battery that is an output voltage at a time point at which a rest period in which no current is applied to the battery ends.

In one example, the method further includes predicting the output voltage of the battery in the specific SOC of the battery when the current is charged or discharged for a time exceeding the preset time based on the fixed parameter, the tuning parameter, and the open-circuit voltage configuring the equivalent circuit model.

In one example, the deriving of the tuning parameter includes changing values of the charge/discharge pulse currents applied to the battery to different magnitudes according to a constant period.

In one example, the deriving of the tuning parameter derives a fixed voltage and a variable resistor and a variable capacitor connected in parallel with each other configuring the equivalent circuit model in a section in which the charge/discharge pulse currents are applied for the preset time. Values of the variable resistor and the variable capacitor are fixed when the charge/discharge pulse currents are applied for the preset time.

In one example, the deriving of the tuning parameter includes deriving the tuning parameter that varies over time. The tuning parameter includes a first tuning parameter multiplied by a resistor of an RC branch configuring the equivalent circuit model and includes a second tuning parameter representing a time constant of the RC branch that varies over time when the charge/discharge pulse currents are applied for a time exceeding the preset time.

In one example, the output voltage of the battery is defined according to the following equation:

$${V}_{e s t} = {V}_{O C V} + I ∗ {R}_{0} + {I}_{{R}_{1}} ∗ {R}_{{1}_{a d a p t i v e}} ∗ {e}^{- \frac{t}{τ}} + I ∗ {R}_{{1}_{a d a p t i v e}} ∗ \left(1 - {e}^{- \frac{t}{τ}}\right) .$$

In this equation, Vₑₛₜ is the estimated output voltage of the battery, V_{OCV} is the open-circuit voltage, R₀ is the fixed resistor, R_{1_{adaptive}} is the resistance value that varies over time and a value obtained by multiplying R₁ that is the resistor connected in parallel with the variable capacitor C1 by the first tuning parameter, and τ is the second tuning parameter representing the time constant that is the tuning parameter of the RC branch.

In one example, the second tuning parameter is derived by adding a value obtained by subtracting the preset time from a current application time to a constant value.

In one example, the first tuning parameter is defined according to the following equation:

$$\text{First tuning parameter} = \left\{\begin{matrix}1 , & t \leq p r e s e t t i m e \\ a {e}^{b t} + c {e}^{d t} , & t > p r e s e t t i m e\end{matrix}\right)$$

In this equation, t is the current application time, and a, b, c, and d are constants determined by the test.

According to embodiments of the present disclosure, it is possible to create a battery voltage prediction model capable of simulating the voltage change (diffusion) due to the transfer of the material (ions) inside the battery according to the input/output of the current for a period of 10 seconds or more. During such a long time, it is difficult to derive the battery voltage prediction model through the hybrid pulse power characterization (HPPC) test. Accordingly, when the current is applied to the battery for the period of 10 seconds or more, reliability in predicting the output voltage of the battery may be increased.

According to the embodiments of the present disclosure, it is possible to use the varying resistor and capacitor without adding the RC branch in order to increase the accuracy of the equivalent circuit model. The processes of extracting the parameters required for the equivalent circuit model and reducing the calculation time that extracts the parameters are thereby simplified.

According to the embodiments of the present disclosure, the controller can create the battery voltage prediction model by using the section in which the SOC is changed in order to test the battery in various states of charge of the battery. In other words, by deriving the variable resistor and the variable capacitor configuring the equivalent circuit model in the tuning section in which the current is applied for more than 10 seconds to create the battery voltage prediction model, it is possible to accurately derive the output voltage of the battery when the battery is charged or discharged for a long time.

It should be understood that the terms “automotive” or “vehicular” or other similar terms as used herein include motor vehicles in general such as passenger automobiles including sports utility vehicles (SUVs), buses, trucks, various commercial vehicles, watercraft including a variety of boats and ships, aircraft, and the like. The terms also include hybrid vehicles, electric vehicles, plug-in hybrid electric vehicles, hydrogen-powered vehicles, and other alternative fuel vehicles (e.g., fuels derived from resources other than petroleum). As referred to herein, a hybrid vehicle is a vehicle that has two or more sources of power, for example, a vehicle that is both gasoline-powered and electric-powered.

The above and other features of the disclosure are discussed hereinbelow.

### BRIEF DESCRIPTION OF THE DRAWINGS

The above and other features of the present disclosure are described in detail with reference to certain examples thereof illustrated in the accompanying drawings, which are given herein below by way of illustration only, and thus do not limit the present disclosure, and wherein:

FIG. 1 is a block diagram showing a battery voltage prediction apparatus according to an embodiment of the present disclosure;

FIG. 2 is a view showing an equivalent circuit model according to an embodiment of the present disclosure;

FIG. 3 is a graph showing an applied current and an output voltage in a hybrid pulse power characterization (HPPC) test according to an embodiment of the present disclosure;

FIG. 4 is an enlarged graph of portion A in FIG. 3;

FIG. 5 is a graph showing a result of conducting the HPPC test for each state of charge (SOC) of a battery according to an embodiment of the present disclosure;

FIG. 6 is a graph for describing reliability of a battery voltage prediction model according to an embodiment of the present disclosure; and

FIG. 7 is a flowchart showing a method of predicting the battery voltage according to an embodiment of the present disclosure.

It should be understood that the appended drawings are not necessarily to scale but present a somewhat simplified representation of various features illustrating the basic principles of the disclosure. The specific design features of the present disclosure as described herein, including, for example, specific dimensions, orientations, locations, and shapes should be determined by the particular intended application and use environment.

In the figures, the same reference numbers refer to the same or equivalent sections of the present disclosure throughout the several figures of the drawings.

### DETAILED DESCRIPTION

Advantages and features of the present disclosure and methods of achieving them should be made clear from the embodiments described in detail below with reference to the accompanying drawings. However, the present disclosure is not limited to the embodiments disclosed below but instead may be implemented in various different forms. These embodiments are only provided so that the present disclosure can be thorough and complete and can fully convey the scope of the present disclosure to those having ordinary skill in the art to which the present disclosure pertains. The present disclosure is defined by the description of the claims. Throughout the specification, the same or equivalent components are denoted by the same reference numerals.

Terms such as “...part”, “...unit”, “...module”, or the like described in the specification mean a unit that processes at least one function or operation, which may be implemented as hardware or software or a combination of hardware and software. When a “...part”, “...unit”, “...module”, or the like of the present disclosure is described as having a purpose or performing an operation, function, or the like, the ...“part”, “...unit”, “...module”, or the like should be considered herein as being “configured to” meet that purpose or to perform that operation or function.

In addition, the reason that names of components may be classified into the first, the second, and the like in this specification is to distinguish the names of similar or identical components. The following description is not necessarily limited to the order conveyed by such classifications or names.

The detailed description illustrates the present disclosure. In addition, the above description shows and describes embodiments of the present disclosure, and the present disclosure may be used in various other combinations, may have various changes, and may be used in different environments. In other words, changes or modifications are possible within the scope of the concept of the present disclosure provided herein, within the scope equivalent to the described disclosure, and/or within the scope of techniques or knowledge in the art. The disclosed embodiments describe modes for implementing the technical spirit of the present disclosure, and various changes required in specific applications and uses of the present disclosure are also possible. Accordingly, the detailed description of the present disclosure is not intended to limit the present disclosure to the disclosed embodiments. In addition, the appended claims should be construed as also including other embodiments.

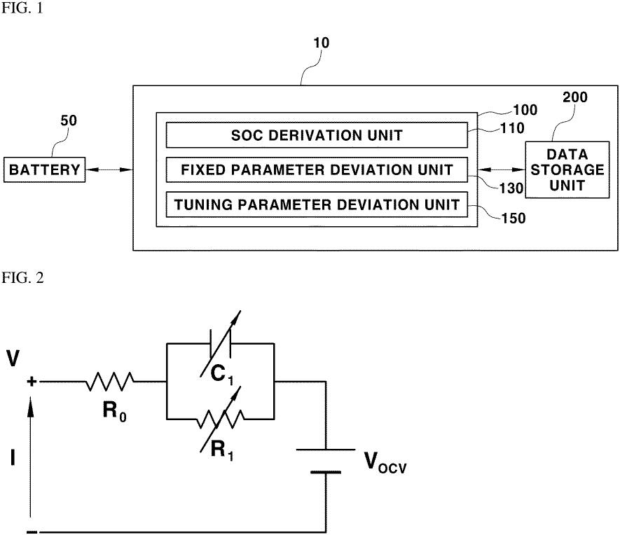

FIG. 1 is a block diagram showing a battery voltage prediction apparatus according to an embodiment of the present disclosure. FIG. 2 is a view showing an equivalent circuit model according to an embodiment of the present disclosure.

Referring to FIGS. 1 and 2, a battery voltage prediction apparatus 10 may predict an output voltage of a battery 50 through an equivalent circuit model. For example, the battery voltage prediction apparatus 10 may be one configuration of a battery management system (BMS). For example, the battery 50 may be a high voltage battery installed in a vehicle and configured to provide power to generate a driving force of the vehicle. The battery management system may monitor the voltage, current, and temperature of the battery 50 to maintain them in optimal states and predict when to replace the battery and may manage the battery such as finding a problem occurring in the battery in advance. The battery voltage prediction apparatus 10 may predict the output voltage of the battery 50 in order to predict the state of the battery 50.

The battery voltage prediction apparatus 10 may include a controller 100 and a data storage unit 200. The controller 100 is a kind of processor or an electronic control unit (ECU) applied to the battery management system. The data storage unit 200 may store values for various parameters derived or measured by the controller 100. For example, the data storage unit 200 may be one of various types of memory. The controller 100 may execute computer-readable codes (e.g., software) stored in the memory 200 and instructions caused by the controller 100. The controller 100 may derive parameters of an equivalent circuit model for predicting the output voltage of the battery 50 based on a result of applying the charge/discharge current to the battery 50. At this time, the controller 100 may test the battery 50 through a hybrid pulse power characterization (HPPC) discharge test.

The controller 100 may include a state of charge (SOC) derivation unit 110, a fixed parameter derivation unit 130, and a tuning parameter derivation unit 150. The SOC derivation unit 110, the fixed parameter derivation unit 130, and the tuning parameter derivation unit 150 may have a configuration classified for each process performed by the controller 100 in a process of performing the HPPC discharge test.

The SOC derivation unit 110 may derive the SOC of the battery 50 according to the input/output currents of the battery 50 and the capacity of the battery 50. In the process of performing the HPPC discharge test, the SOC of the battery 50 may be changed. Accordingly, the SOC derivation unit 100 may calculate the SOC of the battery 50 in the process of tuning the SOC of the battery 50.

When the current is input or output for a preset time, the fixed parameter derivation unit 130 may derive fixed parameters required for the equivalent circuit model based on voltages measured according to the input/output currents of the battery and a change in the time within a preset time. The current that is input or output to the battery 50 may be a pulse current changed according to a constant period for the preset time. The preset time may mean a time for which a pulse current for charging and discharging is applied. For example, in the HPPC discharge test, the time for which the charge/discharge currents are applied may be 10 seconds. In addition, while the HPPC discharge test is conducted, a temperature of the battery 50 may be maintained at a specific temperature.

The equivalent circuit model is configured to test the battery 50 and may be configured to a voltage source Vocv representing an open-circuit voltage (OCV) of the battery 50, a fixed resistor R0 connected to the voltage source Vocv in series, and an RC branch of a variable resistor R1 and a variable capacitor C1.

The fixed parameter derivation unit 150 may derive fixed parameters by the charge/discharge currents applied according to the constant period for the preset time. At this time, the fixed parameter may be the fixed resistor R0, the variable resistor R1, and the variable capacitor C1. When the charge/discharge currents are applied to the battery 50 for the preset time, a resistance value of the variable resistor R1 may not vary for the preset time, and a capacitance of the variable capacitor C1 may not vary for the preset time.

The tuning parameter derivation unit 150 may derive at least one varying tuning parameter required for the equivalent circuit model when the current is input or output for a time exceeding the preset time. The tuning parameter may vary over time. A section in which the current is input or output for a time exceeding the preset time may mean a section for tuning the SOC of the battery 50. The tuning parameter may include a first tuning parameter multiplied by the resistor R1 of the RC branch configuring the equivalent circuit model when the charge/discharge pulse currents are applied for a time exceeding the preset time. The tuning parameter may also include a second tuning parameter representing a time constant of the RC branch changed over time. When the charge/discharge currents are applied to the battery 50 for a time exceeding a preset time, the variable resistor R1 and the variable capacitor C1 may vary according to time. The output voltage of the battery 50 in which the current is charged/discharged for a time exceeding the preset time may be predicted by the equivalent circuit model to which the tuning parameters are applied.

The data storage unit 200 may store the fixed parameters and tuning parameters derived differently for each SOC of the battery 50. Specifically, the test may be conducted in various SOCs of the battery 50. The open-circuit voltage, fixed parameters, and tuning parameters derived by conducting the test for each SOC of the battery 50 are stored in the data storage unit 200. Accordingly, both the fixed parameters and the tuning parameters configuring the equivalent circuit model for each SOC of the battery 50 may be derived to create a battery voltage prediction model.

According to an embodiment of the present disclosure, it is possible to derive the fixed parameters and the tuning parameters configuring the equivalent circuit model through the test of the battery 50 and predict the output voltage of the battery 50 according to the open-circuit voltage, fixed parameters, and tuning parameters for each SOC of the battery 50 stored in the data storage unit 200.

According to an embodiment of the present disclosure, it is possible to create the battery voltage prediction model capable of simulating the voltage change (diffusion) due to the transfer of the material (ions) inside the battery according to the input/output of the current for a relatively long time of 10 seconds or more for which it is difficult to derive the battery voltage prediction model through the HPPC test. Accordingly, it is possible to increase reliability in predicting the output voltage of the battery 50 when the current is applied to the battery 50 for a long time of 10 seconds or more.

According to an embodiment of the present disclosure, it is possible to use the varying resistor and capacitor without adding the RC branch in order to increase the accuracy of the equivalent circuit model. Thus, the process of extracting the parameters required for the equivalent circuit model may be simplified and the calculation time that extracts the parameters may be reduced.

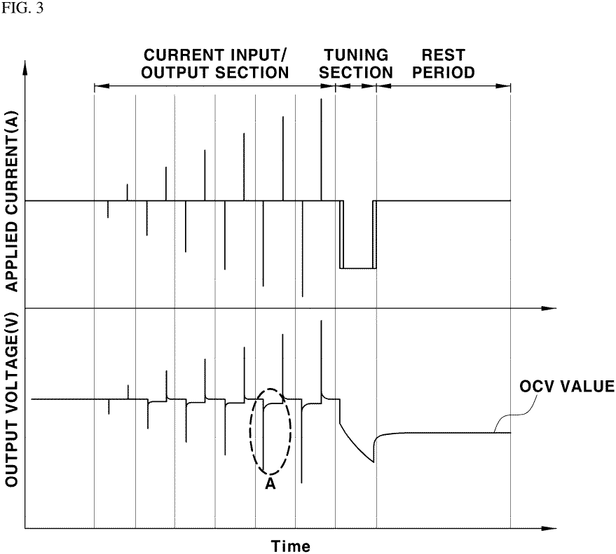

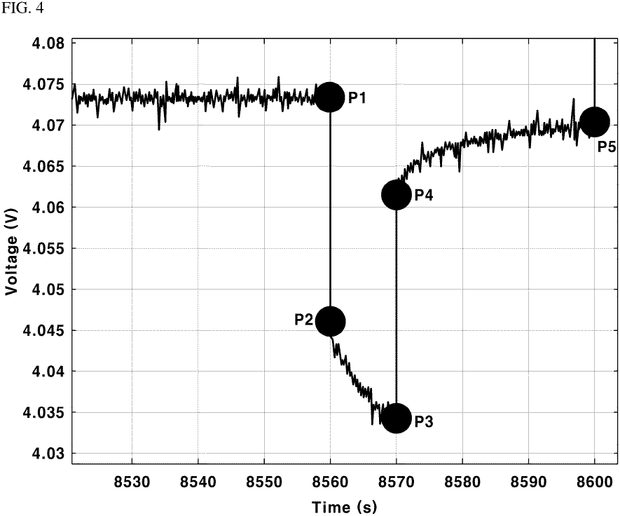

FIG. 3 is a graph showing an applied current and an output voltage in an HPPC test according to an embodiment of the present disclosure. FIG. 4 is an enlarged graph of portion A in FIG. 3.

Referring to FIGS. 1-4, as the charge/discharge pulse currents are applied to the battery 50, the output voltage of the battery 50 may be derived. The controller 100 may monitor the magnitudes of the charge/discharge currents applied to the battery 50 and the output voltage value of the battery 50. The magnitudes of the charge/discharge currents applied to the battery 50 and the output voltage value of the battery 50 may be stored in the data storage unit 200.

Referring to FIG. 2, one cycle for which the voltage of the battery 50 is tested in a specific SOC of the battery 50 may be configured to have a current input/output section in which charge/discharge pulse currents are alternately applied for the preset time. The cycle may also be configured to have a tuning section for tuning the SOC of the battery 50 and a rest period in which no current is applied. In the current input/output section, the charge/discharge pulse currents may be applied to the battery 50 according to a constant period. In addition, the magnitude of the charge/discharge pulse currents applied to the battery 50 may be adjusted by the controller 100. For example, the magnitudes of the charge/discharge pulse currents applied to the battery 50 may be the same or different within the current input/output section. The fixed parameter derivation unit 130 may derive the fixed parameters in the current input/output section according to the constant period for the preset time. When the charge/discharge pulse currents are applied to the battery 50 for the preset time, the parameters configuring the equivalent circuit model may not vary over time. In other words, the fixed parameter derivation unit 130 may derive the fixed parameters including the resistance value and the capacitance configuring the equivalent circuit model in the current input/output section.

Referring to FIG. 4, when the discharge pulse current is applied, the fixed parameter derivation unit 130 may derive the fixed parameters based on the output voltages. A first point P1 may represent a first voltage V1 just before the discharge current is applied, a second point P2 may represent a second voltage V2 just after the discharge current is applied, and a third point P3 may represent a third voltage V3 just before the discharge current is applied and the discharge current is released after the preset time. The fixed parameter derivation unit 130 may derive a fixed resistance R0, which is a value obtained by dividing a value obtained by subtracting the first voltage V1 from the second voltage V2 by the magnitude of the discharge current. The fixed parameter derivation unit 130 may derive a variable resistor R1, which is a value obtained by dividing a value obtained by subtracting the second voltage V2 from the third voltage V3 by the magnitude of the discharge current. However, the variable resistor R1 may be a fixed resistor that does not vary over time in the current input/output section.

Referring back to FIG. 3, the tuning parameter derivation unit 150 may derive the tuning parameters in the tuning section. When the charge/discharge currents are applied to the battery 50 for a time exceeding the preset time, the output voltage of the battery 50 may vary over time according to the voltage change (diffusion) due to the transfer of a material (ions) inside the battery. The tuning parameter derivation unit 150 may derive the tuning parameters that vary over time based on the following equations.

$${C}_{1} = \frac{τ + t}{4 ∗ {R}_{{1}_{a d a p t i v e}}}$$

$$\text{First tuning parameter} = \left\{\begin{matrix}1 , & t \leq p r e s e t t i m e \\ a {e}^{b t} + c {e}^{d t} , & t > p r e s e t t i m e\end{matrix}\right)$$

$$\text{Second tuning parameter} = \left\{\begin{matrix}C o n s t a n t , & t \leq p r e s e t t i m e \\ C o n s t a n t + \left(t - 10\right) , & t > p r e s e t t i m e\end{matrix}\right)$$

In these equations, R_{1_{adaptive}} is a resistance value that varies over time and may be a value obtained by multiplying the variable resistor R1, which is a resistor connected in parallel with the capacitor C1, by the first tuning parameter. The value τ may be the second tuning parameter representing a time constant that is a tuning parameter of the variable resistor R1 and the capacitor C1. The value t may be a current application time in seconds (sec), and a, b, c, and d may be constants determined by the test.

For the first tuning parameter, as the time for which the charge or discharge current is applied increases, the increase rate of the output voltage may decrease. In other words, the first tuning parameter may be expressed as an exponential function that varies over time. The second tuning parameter may be derived by adding a value obtained by subtracting the preset time from the current application time to a constant value. In other words, the second tuning parameter may be expressed as a linear function that increases over time. Referring to the above equation, since the first tuning parameter and the second tuning parameter are expressed as constants within the preset time, the variable resistor R1 and the variable capacitor C1 may not vary in the current input/output section. In addition, the first tuning parameter and the second tuning parameter may vary over time in the tuning section.

The fixed parameter derivation unit 130 may derive the open-circuit voltage OCV of the battery 50, which is the output voltage at a time at which the rest period ends. For example, the rest period may mean a time point after 1,800 seconds from the section in which the tuning section ends. In other words, the open-circuit voltage OCV of the battery 50 may mean the output voltage of the battery 50 at a time point after 1800 seconds in the section in which the tuning section ends.

The battery voltage prediction model may be modeled by the fixed parameters, open-circuit voltage, and tuning parameters derived by the fixed parameter derivation unit 130 and the tuning parameter derivation unit 150.

The controller 100 may predict the output voltage of the battery 50 based on the modeled battery voltage prediction model. The output voltage of the battery 50 may be derived by the following equations.

$$\begin{matrix}{V}_{e s t} = {V}_{O C V} + I ∗ {R}_{0} + {I}_{{R}_{1}} ∗ {R}_{{1}_{a d a p t i v e}} ∗ {e}^{- \frac{t}{τ}} + I ∗ {R}_{{1}_{a d a p t i v e}} ∗ \left(1 - {e}^{- \frac{t}{τ}}\right) \\ {I}_{{R}_{1}} = I - {I}_{{C}_{2}} = I - {R}_{{1}_{a d a p t i v e}} ∗ {C}_{1} \frac{d {I}_{{ε}_{2}}}{d t}\end{matrix}$$

In these equations, Vₑₛₜ may be the estimated output voltage of the battery, V_{OCV} may be the open-circuit voltage. R₀ may be the fixed resistor. R_{1_{adaptive}} may be the resistance value that varies over time and a value obtained by multiplying R₁ that is the resistor connected in parallel with the variable capacitor C1 by the first tuning parameter, and τ may be the second tuning parameter representing the time constant that is the tuning parameter of R₁ and the variable capacitor C1.

According to an embodiment of the present disclosure, the controller 100 may create the battery voltage prediction model using the section in which the SOC is changed to test the battery 50 in various SOCs of the battery 50. In other words, the controller 100 may create the battery voltage prediction model by deriving the variable resistor and the variable capacitor configuring the equivalent circuit model in the tuning section to which the current is applied for the time of more than 10 seconds. Thus, the output voltage of the battery 50 when the battery 50 is charged or discharged for the long time may be accurately derived. Accordingly, a highly reliable battery voltage prediction model may be created compared to the method of configuring the equivalent circuit model based on the result of applying the charge/discharge currents for 10 seconds.

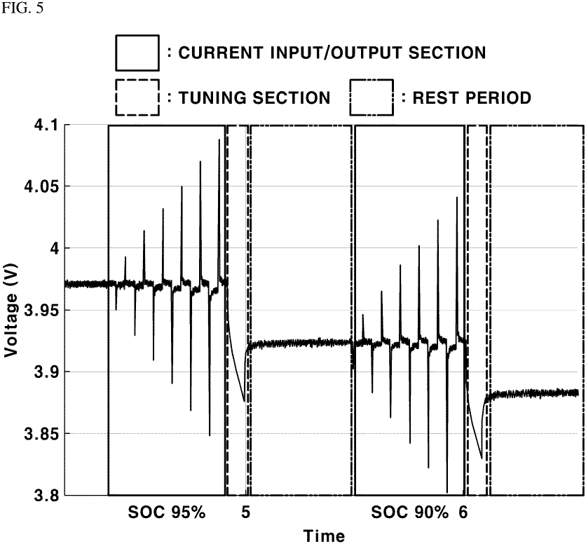

FIG. 5 is a graph showing a result of conducting the HPPC test for each SOC of a battery according to an embodiment of the present disclosure.

Referring to FIGS. 1 and 5, the controller 100 may derive the fixed parameters and the tuning parameters by conducting the test in various SOCs of the battery 50. When the SOC is 95%, the controller 100 may derive the fixed parameters in the current input/output section, derive the tuning parameters in the tuning section, and derive the open-circuit voltage in the rest period. As the discharge current is applied to the battery 50 in the tuning section, the SOC of the battery 50 may be lowered to 90%, and the controller 100 may derive the fixed parameters and the tuning parameters when the SOC of the battery 50 is 90%. The controller 100 may test the battery 50 while continuously changing the SOC to model the battery voltage prediction model.

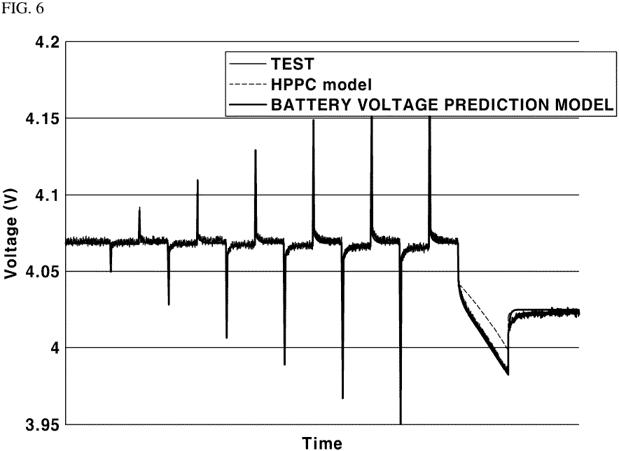

FIG. 6 is a graph for describing reliability of the battery voltage prediction model according to an embodiment of the present disclosure.

In the conventional HPPC model, a voltage change due to a battery specific resistance (pure ohmic resistance), an OCV change, and a voltage change due to the charge transfer in a short current section upon a test through the application of the charge/discharge currents within 10 seconds may be simulated. However, since the voltage change of the battery due to the transfer of ions, which is a material inside the battery, occurs relatively slowly, it is difficult for the HPPC model to simulate the voltage change of the battery due to the transfer of ions. Thus, it is not possible to accurately predict the output voltage of the battery upon charging and discharging for a long time. FIG. 6 shows that the voltage behavior derived from the test and the output voltage predicted through the HPPC model are similar in the current input/output section but have a significant difference in the tuning section.

In the battery voltage prediction model according to an embodiment of the present disclosure, the tuning parameter that varies depending on the time derived from the tuning section upon the battery test is applied. Thus, it is possible to accurately predict the output voltage of the battery that varies over time even when the battery is charged or discharged for the long time of 10 seconds or more. FIG. 6 shows that the voltage behavior derived from the test and the output voltage predicted through the battery voltage prediction model have similar values in both the current input/output section and the tuning section.

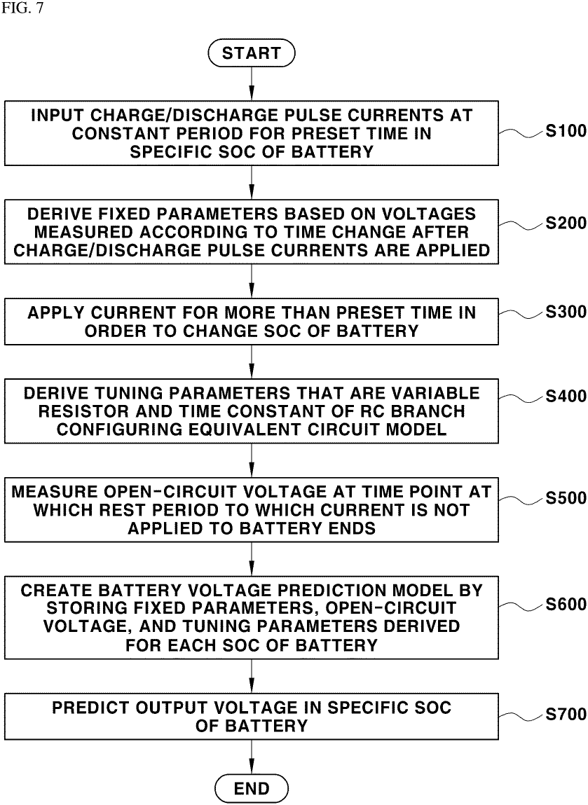

FIG. 7 is a flowchart showing a method of predicting the battery voltage according to an embodiment of the present disclosure.

Referring to FIG. 7, the charge/discharge pulse currents may be input to the battery at the constant period for the preset time in a specific SOC of the battery (S100).

The controller may derive the fixed parameters based on the voltages measured according to time change after the charge/discharge pulse currents are applied. The controller may derive the fixed parameters based on the output voltage of the battery for the preset time for which the pulse currents for charging and discharging are applied (S200).

The controller may apply the current to the battery for a time exceeding the preset time for changing the SOC of the battery. For example, in order to change the SOC of the battery from 95% to 90%, the controller may apply the discharge current to the battery for more than 10 seconds that is the preset time (S300).

The controller may derive the tuning parameters that are the variable resistor and the time constant of the RC branch configuring the equivalent circuit model. Specifically, the controller may derive the first tuning parameter multiplied by the fixed resistance value in order to represent the variable resistor that varies over time and the second parameter representing the time constant that is the parameter for tuning the RC branch (S400).

The controller may measure the open-circuit voltage, which is a voltage at the time point at which the rest period in which no current is applied to the battery ends. The controller may store the measured open-circuit voltage and the fixed parameters and tuning parameters derived in the above process in the data storage unit (S500).

The controller may test the battery for each SOC of the battery and store the fixed parameters, open-circuit voltage, and tuning parameters derived for each SOC of the battery to model the battery voltage prediction model (S600).

The controller may predict the output voltage in the specific SOC of the battery based on the modeled battery voltage prediction model (S700).

While the embodiments of the present disclosure have been described above with reference to the accompanying drawings, those having ordinary skill in the art to which the present disclosure pertains should understand that the present disclosure may be carried out in other specific forms without changing the technical spirit or essential features thereof. Accordingly, it should be understood that the above-described embodiments are illustrative and not restrictive in all respects.

What is claimed is:

1. A battery voltage prediction apparatus for modeling a battery voltage prediction model that predicts an output voltage of a battery over time by charging and discharging a current for each state of charge (SOC) of the battery, the battery voltage prediction apparatus comprising:
an SOC derivation unit configured to derive the SOC of the battery according to a current that is input or output to the battery and a capacity of the battery;
a fixed parameter derivation unit configured to derive fixed parameters required for an equivalent circuit model based on voltages measured according to input/output currents of the battery and a time change within a preset time when the current is input or output for the preset time; and
a tuning parameter derivation unit configured to derive at least one tuning parameter that varies depending on a time required for the equivalent circuit model when the current is input or output for a time exceeding the preset time.

2. The battery voltage prediction apparatus of claim 1, wherein the equivalent circuit model is a model for predicting the output voltage of the battery and configured to a voltage source representing an open-circuit voltage (OCV) of the battery, a fixed resistor connected to the voltage source in series, and an RC branch of a variable resistor and a variable capacitor.

3. The battery voltage prediction apparatus of claim 1, wherein
the tuning parameter includes a first tuning parameter multiplied by a resistor of an RC branch configuring the equivalent circuit model and a second tuning parameter representing a time constant of the RC branch varying over time when the charge/discharge pulse currents are applied for a time exceeding the preset time, and
the output voltage of the battery at which the current is charged or discharged for a time exceeding the preset time is predicted by the equivalent circuit model to which the tuning parameter is applied.

4. The battery voltage prediction apparatus of claim 1, wherein a section in which the current is input or output for a time exceeding the preset time means a section in which the SOC of the battery is tuned.

5. The battery voltage prediction apparatus of claim 1, wherein the fixed parameter derivation unit derives the fixed parameter in the section in which the current is input or output according to a constant period for the preset time.

6. The battery voltage prediction apparatus of claim 5, wherein the current that is input or output to the battery is a pulse current that is changed according to the constant period for the preset time.

7. The battery voltage prediction apparatus of claim 1, wherein one period in which a voltage of the battery is tested in a specific SOC of the battery is configured to include a current input/output section in which charge/discharge pulse currents are alternately applied for the preset time, a tuning section in which the SOC of the battery is tuned, and a rest period in which no current is applied.

8. The battery voltage prediction apparatus of claim 7, wherein
the fixed parameter derivation unit derives the fixed parameter including a resistance value and a capacitance configuring the equivalent circuit model in the current input/output section,
the fixed parameter derivation unit derives an open-circuit voltage (OCV) of the battery that is an output voltage at a time point at which the rest period ends, and
the tuning parameter derivation unit derives the tuning parameter in the tuning section.

9. The battery voltage prediction apparatus of claim 1, further comprising:
a data storage unit configured to store the fixed parameter and the tuning parameter derived differently for each SOC of the battery.

10. The battery voltage prediction apparatus of claim 1, wherein the output voltage of the battery is defined as:
$$\begin{matrix}{V}_{e x t} = \\ {V}_{O C V} + I ∗ {R}_{0} + {I}_{{R}_{i}} ∗ {R}_{{1}_{a d a p t i v e}} ∗ {e}^{- \frac{t}{x}} + I * {R}_{{1}_{a d a p t i v e}} ∗ \left(1 - {e}^{- \frac{t}{x}}\right) , \text{and}\end{matrix}$$
wherein vₑₛₜ is the estimated output voltage of the battery, v_{ocv} is the open-circuit voltage, R₀ is the fixed resistor, R_{1_{adaptive}} is the resistance value that varies over time and a value obtained by multiplying R₁ that is the resistor connected in parallel with the variable capacitor C1 by the first tuning parameter, and τ is the second tuning parameter representing the time constant that is the tuning parameter of R₁ and the variable capacitor.

11. The battery voltage prediction apparatus of claim 10, wherein
the R₀, the R₁, the capacitance, and the open-circuit voltage are derived by the fixed parameter derivation unit,
the tuning parameter derivation unit derives the first tuning parameter and the second tuning parameter that vary according to a current application time when the current is input or output for a time exceeding the preset time, and
the second tuning parameter is derived by adding a value obtained by subtracting the preset time from a current application time to a constant value.

12. The battery voltage prediction apparatus of claim 11, wherein the first tuning parameter is defined as:
$$\text{First tuning parameter} = \left\{\begin{matrix}1 , t \leq p r e s e n t t i m e \\ a {e}^{b t} + c {e}^{d t} , t > p r e s e t t i m e\end{matrix}\right) , \text{and}$$
wherein t is the current application time, and a, b, c, and d are constants determined by the test.

13. A battery voltage prediction method of modeling a battery voltage prediction model that predicts an output voltage of a battery over time by charging and discharging a current for each state of charge (SOC) of the battery, the method comprising:
deriving a fixed parameter required for an equivalent circuit model based on voltages measured according to a time change by applying charge/discharge pulse currents for a preset time to the battery in a specific SOC of the battery;
deriving at least one tuning parameter that varies according to a time required for the equivalent circuit model in a current input/output section for a time exceeding the preset time to the battery in order to change the SOC of the battery; and
deriving an open-circuit voltage of the battery that is an output voltage at a time point at which a rest period in which no current is applied to the battery ends.

14. The method of claim 13, further comprising:
predicting the output voltage of the battery in the specific SOC of the battery when the current is charged or discharged for a time exceeding the preset time based on the fixed parameter, the tuning parameter, and the open-circuit voltage configuring the equivalent circuit model.

15. The method of claim 13, wherein the deriving of the tuning parameter includes changing values of the charge/discharge pulse currents applied to the battery to different magnitudes according to a constant period.

16. The method of claim 15, wherein
the deriving of the tuning parameter derives a fixed voltage and a variable resistor and a variable capacitor connected in parallel with each other configuring the equivalent circuit model in a section in which the charge/discharge pulse currents are applied for the preset time, and
values of the variable resistor and the variable capacitor are fixed when the charge/discharge pulse currents are applied for the preset time.

17. The method of claim 13, wherein
the deriving of the tuning parameter includes deriving the tuning parameter that varies over time, and
the tuning parameter includes a first tuning parameter multiplied by a resistor of an RC branch configuring the equivalent circuit model and includes a second tuning parameter representing a time constant of the RC branch that varies over time when the charge/discharge pulse currents are applied for a time exceeding the preset time.

18. The method of claim 17, wherein the output voltage of the battery is defined as:
$$\begin{matrix}{V}_{e x t} = \\ {V}_{O C V} + I ∗ {R}_{0} + {I}_{{R}_{i}} ∗ {R}_{{1}_{a d a p t i v e}} ∗ {e}^{- \frac{t}{x}} + I * {R}_{{1}_{a d a p t i v e}} ∗ \left(1 - {e}^{- \frac{t}{x}}\right) , \text{and}\end{matrix}$$
wherein Vₑₛₜ is the estimated output voltage of the battery, V_{ocv} is the open-circuit voltage, R₀ is the fixed resistor, R_{1adaptive} is the resistance value that varies over time and a value obtained by multiplying R₁ that is the resistor of the RC branch by the first tuning parameter, and τ is the second tuning parameter representing the time constant that is the tuning parameter of the RC branch.

19. The method of claim 18, wherein the second tuning parameter is derived by adding a value obtained by subtracting the preset time from a current application time to a constant value.

20. The method of claim 18, wherein the first tuning parameter is defined as:
$$\text{First tuning parameter} = \left\{\begin{matrix}1 , t \leq p r e s e n t t i m e \\ a {e}^{b t} + c {e}^{d t} , t > p r e s e t t i m e\end{matrix}\right) , \text{and}$$
wherein t is the current application time, and a, b, c, and d are constants determined by the test.
